(19) United States
(12) Patent Application Publication
(10) Pub. No.: US 2010/0196528 A1
(43) Pub. Date: Aug. 5, 2010

(54) STAMPER AND METHOD PRODUCING THE SAME

(75) Inventors: Yoshiyuki KAMATA, Tokyo (JP); Takuya SHIMADA, Kawasaki-shi (JP); Satoshi SHIROTORI, Yokohama-shi (JP); Masatoshi SAKURAI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/695,936

(22) Filed: Jan. 28, 2010

(30) Foreign Application Priority Data
Jan. 30, 2009 (JP) 2009-020693

(51) Int. Cl. B29C 59/02; G03F 7/20

(52) U.S. Cl. 425/385; 430/296

(57) ABSTRACT

According to one embodiment, a stamper includes patterns corresponding to recording tracks or recording bits in a data region and patterns corresponding to information in a servo region formed in protrusions and recesses on a front side of the stamper, in which an inner periphery and an outer periphery are processed and, on a back side, an inner peripheral edge, an outer peripheral edge and a main surface of the back side lie on the same plane.

### CROSS-REFERENCE TO RELATED APPLICATIONS

This application is based upon and claims the benefit of priority from Japanese Patent Application No. 2009-020693, filed Jan. 30, 2009, the entire contents of which are incorporated herein by reference.

### BACKGROUND

1. Field

One embodiment of the present invention relates to a stamper and a method of producing the same.

2. Description of the Related Art

Recently, in a magnetic recording medium installed in hard disk drives (HDDs), there is an increasing problem of disturbance of enhancement of track density due to interference between adjacent tracks. In particular, a serious technical subject is reduction in fringing of a magnetic field from a write head.

To solve such a problem, a discrete track recording medium (DTR medium) has been developed in which recording tracks are physically separated from each other. Since the DTR medium can reduce a side-erase phenomenon in writing and a side-read phenomenon in reading, it can increase the track density. Therefore, the DTR medium is expected as a high-density magnetic recording medium.

Also, a bit patterned medium (BPM) has been developed in which read and write are performed for a single magnetic dot as a single recording cell have been developed as a high-density magnetic recording medium that can suppress thermal fluctuation phenomenon and medium noise.

To produce individual DTR media or BPMs by electron beam (EB) lithography highly increases production cost. In this connection, it is effective in reducing the production cost to produce DTR media or BPMs in such a manner that an Ni stamper is produced from a master plate on which fine patterns are formed by electron beam (EB) lithography, many resin stampers are produced from the Ni stamper by injection molding, and DTR media or BPMs are produced from the resin stampers by UV imprint (UV curing imprint). This method enables to mass-produce the DTR media or BPMs at low cost.

A similar technology is adopted for production of optical disks. When optical disks are produced from an Ni stamper by injection molding, it is known that the Ni stamper can endure 100,000 shots of the injection molding.

However, it was found that, when the resin stampers for producing the DTR media or BMPs by injection molding are produced from a Ni stamper, the Ni stamper deforms to an extent that exceeds an allowable range after several thousand shots and also a shape of the resin stampers deteriorates. This is considered to be because fineness of patterns of the DTR medium or BMP are one tenth or less of that of patterns of an optical disk, and thus it is necessary to apply mold clamping force as high as 50 to 70 tons during injection molding.

Jpn. Pat. Appln. KOKAI Publication No. 5-2775 discloses a method of polishing the back side of a stamper to keep uniformity of an optical disk surface. However, even when resin stampers for producing the DTR media or BPMs are produced by adopting the method described in Jpn. Pat. Appln. KOKAI Publication No. 5-2775, the lifetime until the Ni stamper deforms exceeding an allowable range cannot be improved.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a plan view showing a discrete track recording medium (DTR medium);

FIG. 2 is a plan view showing a bit patterned medium (BPM);

FIGS. 3A to 3G are cross-sectional views showing a method of producing a stamper according to an embodiment of the invention;

FIGS. 4A and 4B are plan views showing punching of a stamper;

FIGS. 5A to 5I are cross-sectional views showing a method of producing a magnetic recording medium (DTR medium or BPM);

FIGS. 6A to 6G are cross-sectional views showing a method of producing a mother stamper according to an embodiment of the invention;

FIGS. 7A to 7F are cross-sectional views showing a method of producing a son stamper and a daughter stamper according to an embodiment of the invention; and

FIG. 8 is a diagram showing relationship between difference in thickness in a stamper surface and amount of RRO displacement.

### DETAILED DESCRIPTION

Various embodiments according to the invention will be described hereinafter with reference to the accompanying drawings. In general, according to one embodiment of the invention, there is provided a stamper comprising: patterns corresponding to recording tracks or recording bits in a data region and patterns corresponding to information in a servo region formed in protrusions and recesses on a front side of the stamper, wherein an inner periphery and an outer periphery are processed and, on a back side, an inner peripheral edge, an outer peripheral edge and a main surface of the back side lie on the same plane.

According to another embodiment of the invention, there is provided a method of producing a stamper, comprising: applying an electron beam resist to a substrate; drawing pattern corresponding to recording tracks or recording bits in a data region and patterns corresponding to information in a servo region on the electron beam resist by electron beam lithography, followed by developing to form protrusions and recesses; forming a conductive film on the protrusions and recesses of the electron beam resist followed by forming a Ni electroforming layer by electroforming; peeling off the Ni electroforming layer to form a stamper; duplicating a stamper by repeating forming and peeling-off of the Ni electroforming layer, as required; and processing an inner periphery and an outer periphery of the stamper followed by polishing a back side of the stamper.

The inventors studied the reason why a lifetime until an Ni stamper deforms to an extent exceeding an allowable range becomes shorter when resin stampers for producing DTR media or BPMs are produced from the Ni stamper by injection molding. As a result, it was found that when there are burrs on a back side of the Ni stamper and the stamper is set to a mold of an injection molding machine, a gap is formed between the mold and the stamper. Further, when mold clamping force as high as 50 to 70 tons is applied to the structure, high load is applied to the Ni stamper to cause deformation. Herein, the burr is defined as a protrusion having a height exceeding the surface roughness (Ra) of a main surface of a back side free from burrs.

The burrs on the back side of the Ni stamper are generated when inner and outer peripheries of the stamper are pressed with a punching blade. At this time, heights of the burrs generated at the inner and outer peripheries of the stamper are usually about 15 μm. In a conventional method, a protective film is applied to a front side (a side on which patterns are formed) of the produced Ni stamper, the back side thereof is polished, and thereafter the inner and outer peripheries of the stamper are pressed. Therefore, at the time of injection molding, burrs remain.

According to the method of the invention, a back side is polished after the inner and outer peripheries of the stamper are processed. Therefore, there is no burr remaining during the injection molding. As a result, a gap is hardly formed between the mold and the stamper when the stamper is set to the mold of the injection molding machine and, even when mold clamping force as high as 50 to 70 tons is applied, high load is difficult to be applied on the Ni stamper, resulting in a prolonged lifetime until deformation is caused in the Ni stamper.

Embodiments of the invention will be described below with reference to drawings.

FIG. 1 shows a plan view in a circumferential direction of a discrete track medium (DTR medium) 1. As shown in FIG. 1, along a circumferential direction of the medium 1, a servo region 2 and a data region 3 are alternately formed. The servo region 2 includes a preamble section 21, an address section 22 and a burst section 23. The data region 3 includes discrete tracks 31 separated from each other.

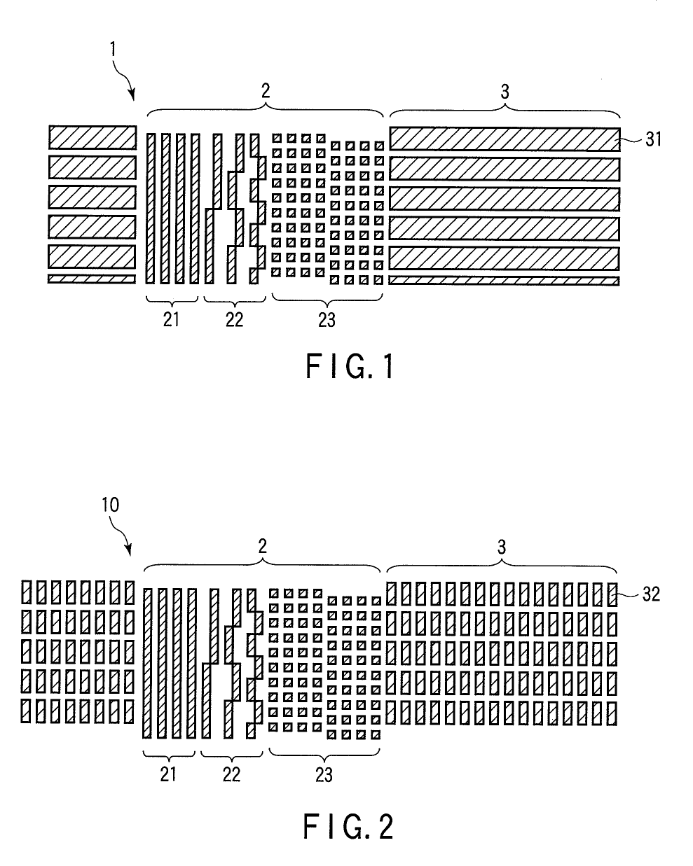

FIG. 2 shows a plan view in a circumferential direction of a bit patterned medium (BPM) 10. As shown in FIG. 2, the servo region 2 has the same configuration as that of FIG. 1. The data region 3 includes magnetic dots 32 separated from each other.

In the invention, there is produced a stamper where patterns corresponding to recording tracks or recording bits in the data region and patterns corresponding to information of the servo region of the DTR medium shown in FIG. 1 or the BPM shown in FIG. 2 are formed in protrusions and recesses.

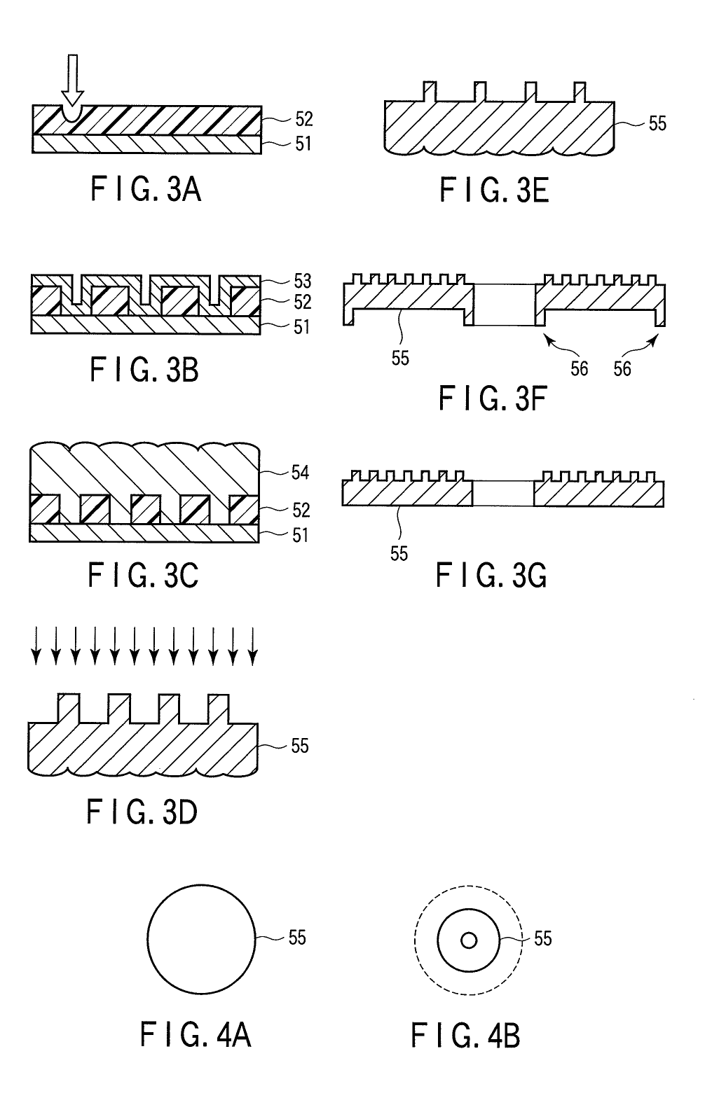

A method of producing a Ni stamper according to an embodiment of the invention will be described below with reference to FIGS. 3A to 3F.

As shown in FIG. 3A, a 6-inch Si wafer was prepared as a substrate 51. On the other hand, a resist ZEP-520A (trade name, manufactured by Zeon Corporation) was diluted to two times with anisole, followed by filtering with a 0.05 μm filter, and thereby a resist solution was prepared. The resist solution was spin-coated on the substrate 51 and pre-baked at 200° C. for 3 minutes, thereby a resist layer 52 having a thickness of about 50 nm was formed. Then, with an electron beam drawing apparatus having a ZrO/W thermal field emission electron gun emitter and under the condition of an acceleration voltage of 50 kV, desired patterns were directly drawn on the resist layer 52 on the substrate 51. The electron beam drawing apparatus has a so-called X-θ stage drive system that has a moving mechanism of a moving axis in at least one direction and a revolving mechanism. When patterns were drawn, a signal source was used which generates in synchronization signals to form servo patterns, burst patterns, address patterns and track patterns, signals sent to the stage driving system of the electron beam drawing apparatus and signals to control deflection of an electron beam. During the drawing, the stage was rotated at a CLV (constant linear velocity) of a linear velocity of 500 mm/s and moved also in a radial direction. Furthermore, for every one rotation, an electron beam was deflected and thereby a track region that forms concentric circles was drawn. At this time, 7.8 nm of movement for every one rotation and 10 rotations formed one track (corresponding to one address bit). Next, the substrate was immersed in a developing solution ZED-N50 (trade name, manufactured by Zeon Corporation) for 90 seconds to develop the resist, followed by rinsing by immersing in ZMD-B (trade name, manufactured by Zeon Corporation) for 90 seconds, further followed by drying by blowing air, and thereby a resist master plate was prepared.

As shown in FIG. 3B, a conductive film 53 was deposited by sputtering on the surface of the resist master plate. The conductive film 53 was made of pure Ni or an alloy prepared by adding a little amount of V or Ru to Ni. Specifically, a chamber 8 was evacuated to 8×10⁻³ Pa, followed by introducing an argon gas to control pressure in the chamber to 1 Pa, further followed by sputtering for 40 seconds by applying DC power of 400 W, and thereby a conductive film 53 having a thickness of about 10 nm was formed.

As shown in FIG. 3C, the resist master plate on which the conductive film 53 was formed was immersed in a nickel sulfamate plating solution (trade name: NS-160, manufactured by Showa Chemical Corporation) to electroform Ni for 90 minutes, thereby an electroforming layer 54 having a thickness of about 300 μm was formed. One example of electroforming conditions is as follows:

Nickel sulfamate: 600 g/L

Boric acid: 40 g/L

Surfactant (sodium lauryl sulfate): 0.15 g/L

Temperature of a solution: 55° C.

pH: 4.0

Current density: 20 A/dm².

As shown in FIG. 3D, the electroforming layer 54 and conductive film 53 were peeled off from the resist master plate. In this state, resist residues adhered to the conductive film 53; accordingly, the resist residues were removed by oxygen RIE (reactive ion etching). Specifically, the chamber was evacuated, followed by introducing an oxygen gas at 100 ml/min to control pressure in the chamber to 4 Pa, further followed by oxygen RIE for 20 minutes by applying power of 100 W, and thereby a Ni stamper 55 containing the conductive film and electroforming layer was obtained.

As shown in FIG. 3E, as required, the stamper may be slimmed. For example, when the Ni stamper 55 is immersed in sulfamic acid controlled to pH 2 for 30 minutes, a width of patterns may be slimmed by 10 to 15 nm.

As shown in FIG. 3F, before a back side was polished, inner and outer peripheries of the Ni stamper 55 were punched. The Ni stamper 55 formed to have a diameter larger than a target diameter as shown in FIG. 4A was punched to make inner and outer peripheries have target diameters as shown in FIG. 4B. Specifically, a protective film (trade name: Silitect) was applied to the surface of the Ni stamper 55, followed by setting the Ni stamper 55 on a punching apparatus (trade name: OMICRON, manufactured by SIBERT), further followed by punching with a ring-shaped metal blade having an outer diameter of 75 mm and an inner diameter of 7 mm centering to a center of patterns of the stamper 55. When a back side of the Ni stamper 55 was observed after punching, burrs 56 having a height of about 15 μm were formed at inner and outer peripheral edges.

As shown in FIG. 3G, a back side of the Ni stamper 55 after punching was subjected to mirror polishing. Herein, the mirror polishing is defined as polishing to a level where the surface roughness (Ra) is substantially 50 nm or less and light reflection is possible. In the embodiment, buffing is used as a mirror polishing method. The buff polishing method is a polishing method in which a polishing cloth impregnated with a paste polishing agent or a suspension (slurry) of diamond or aluminum oxide is used to polish. When the back side of the Ni stamper 55 was mirror-polished by such a method, burrs at inner and outer peripheral edges, which were generated in FIG. 3F, may be completely removed, whereby, on a back side of the Ni stamper 55, the inner peripheral edge, the outer peripheral edge and the main surface of the back side were formed so as to lie on the same plane.

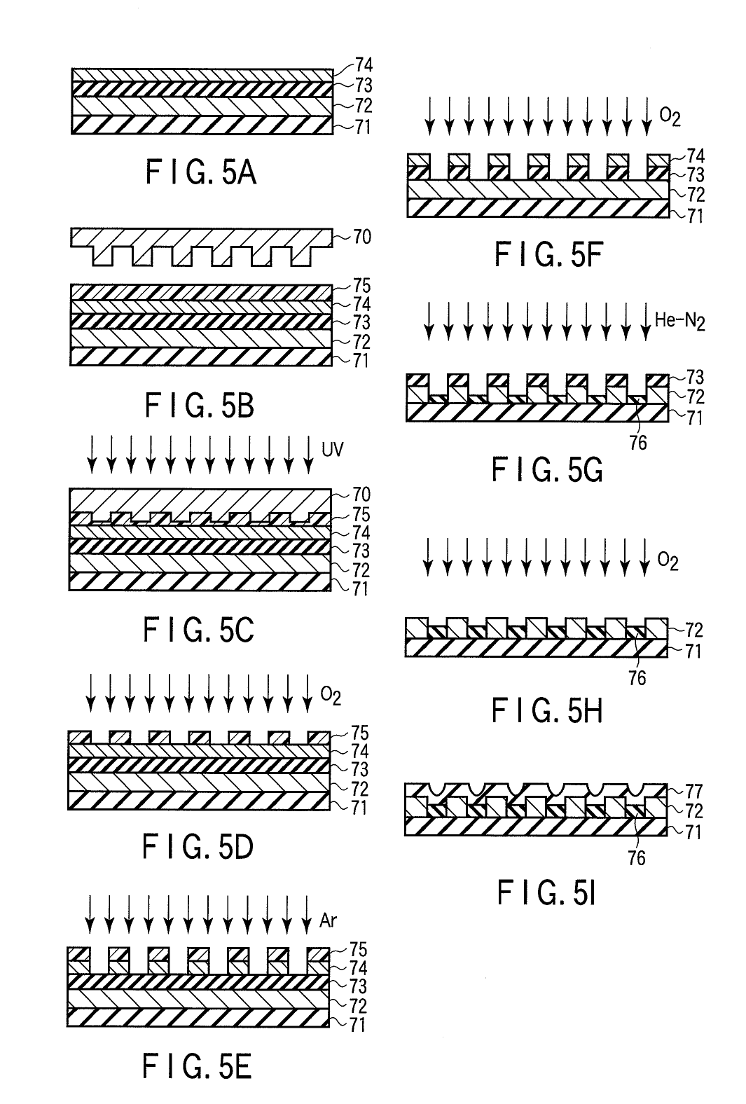

Next, with reference to FIGS. 5A to 5I, a method of producing a magnetic recording medium (DTR medium or BPM) with a stamper will be described.

First, the Ni stamper 55 produced according to the method described with reference to FIGS. 3A to 3G is set on an injection molding machine (manufactured by Toshiba Machine Co., Ltd.) and resin stampers 70 are prepared by injection molding. As a resin material, cyclic olefin polymer ZEONOR 1060R (trade name, manufactured by Zeon Corporation) or polycarbonate AD5503 (trade name, manufactured by Teijin Chemicals Ltd.) is used.

As shown in FIG. 5A, on a glass substrate 71, a soft magnetic underlayer (not shown) made of CoZrNb and having a thickness of 120 nm, an orientation controlling underlayer (not shown) made of Ru and having a thickness of 20 nm, a magnetic recording layer 72 made of CoCrPt—SiO₂ and having a thickness of 15 nm, an etching protective layer 73 made of carbon and having a thickness of 15 nm and a metal layer 74 having a thickness of 3 to 5 nm are sequentially deposited. Herein, for the purpose of simplification, the soft magnetic underlayer and the orientation controlling layer are not shown in the drawing.

As the metal layer 74, a metal excellent in the adhesiveness with a UV resist (photopolymer agent, 2P agent) described below and completely stripped off during etching with He+N₂ gas described below is used. Specific examples thereof include CoPt, Cu, Al, NiTa, Ta, Ti, Si, Cr, NiNb and ZrTi. In particular, CoPt, Cu and Si are excellent in both the adhesiveness with the UV resist and stripping properties by the He—N₂ gas.

As shown in FIG. 5B, the UV resist 75 is spin-coated on the metal layer 74 so as to be 50 nm in thickness. The UV resist 75 contains a monomer, an oligomer and a polymerization initiator and exhibits UV curability. For example, a composition that contains 85% of isobornyl acrylate (IBOA) as the monomer, 10% of polyurethane diacrylate (PUDA) as the oligomer and 5% of DAROCURE 1173 (trade name) as the polymerization initiator may be used. The resin stamper 70 is disposed so as to face the resist 74.

As shown in FIG. 5C, the resin stamper 70 is used to imprint and form protrusions of the UV resist 75 corresponding to recesses of the resin stamper 70, followed by applying UV-rays through the resin stamper 70 to cure the UV resist 75.

As shown in FIG. 5D, after the resin stamper 70 is removed, resist residues remaining on bottoms of the recesses of the patterned UV resist 75 are removed. For example, an ICP (inductively-coupled plasma) etching apparatus is used with the chamber pressure set to 2 mTorr by introducing oxygen as a process gas, coil RF power and platen RF power both set to 100 W and an etching time set to 30 seconds.

As shown in FIG. 5E, with a pattern of the UV resist 75 as a mask, ion beam etching is applied with Ag gas to etch the metal layer 74. The process is not necessarily applied. For instance, when the resist residues are removed, the resist residues and metal layer may be etched under etching conditions high in anisotropy. Specifically, when platen RF power is raised to around 300 W by the ICP etching apparatus, the etching anisotropy may be enhanced. When Si is used for the metal layer 74, a CF₄ gas may be used for etching.

As shown in FIG. 5F, with a pattern of the UV resist 75 as a mask, the etching protective film 73 is patterned. For instance, with the ICP etching apparatus, O₂ is introduced as a process gas to control chamber pressure to 2 mTorr, and coil RF power and platen RF power respectively are set to 100 W and an etching time to 30 seconds.

As shown in FIG. 5G, with a pattern of the etching protective layer 73 as a mask, ion beam etching is applied with He or He+N₂ (mixing ratio 1:1), and thereby, the magnetic recording layer 72 is partially etched to form protrusions and recesses, and the magnetic recording layer 72 remaining in the recesses is demagnetized to form a nonmagnetic layer 76. At this time, an ECR (electron cyclotron resonance) ion gun is preferably used. The magnetic recording layer 72 is etched under conditions of, for example, microwave power of 800 W and an acceleration voltage of 1000 V for 20 seconds, and thereby recesses having a depth of 10 nm are formed and a nonmagnetic layer 76 demagnetized and having a thickness of 5 nm is formed. At the same time, a remaining metal layer (such as Cu) 74 is removed. This is because when the metal layer 74 remains, in the next step, the etching protective layer (carbon) 73 may not be stripped off by oxygen RIE.

As shown in FIG. 5H, the pattern of the etching protective layer (carbon) 73 is removed. For example, with an oxygen gas, the RIE (reactive ion etching) is applied under conditions of 100 mTorr, 100 W and an etching time of 30 seconds.

As shown in FIG. 5I, a surface protective film 77 having a thickness of 4 nm and made of carbon is formed by CVD (chemical vapor deposition). By coating a lubricant on the surface protective film 77, a DTR medium or BPM is produced.

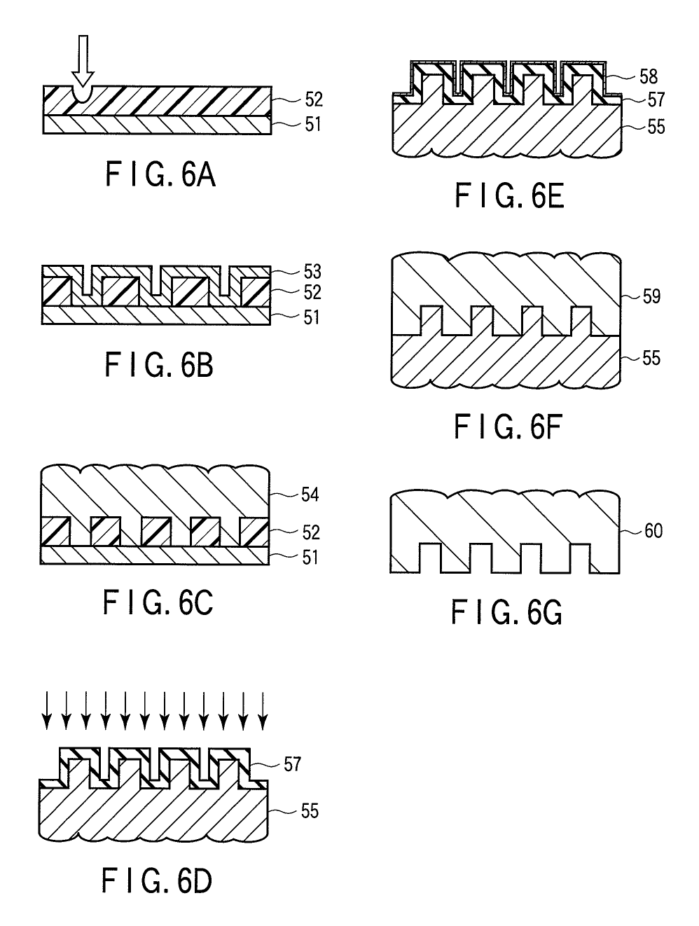

Next, with reference to FIGS. 6A to 6G, a method of producing a mother stamper according to an embodiment of the invention will be described.

As shown in FIG. 6A, a resist layer 52 is applied to a substrate 51, followed by applying the electron beam (EB) drawing, further followed by developing to produce a resist master plate. As shown in FIG. 6B, a conductive film 53 is deposited on a surface of the resist master plate. As shown in FIG. 6C, an electroforming layer 54 is formed by electroforming. These steps are the same as FIGS. 3A to 3C.

As shown in FIG. 6D, the electroforming layer 54 and conductive film 53 are peeled off from the resist master plate to form a Ni stamper. The Ni stamper thus formed is called a father stamper 55. The surface of the father stamper 55 is oxidized by oxygen RIE to form an oxide layer 57. The oxide layer 57 works as a passivation layer and a peeling layer. As shown in FIG. 6E, a conductive film 58 is deposited on the oxide layer 57 on the surface of the father stamper 55. As shown in FIG. 6F, an electroforming layer 59 is formed by electroforming. As shown in FIG. 6G, the electroforming layer 59 and conductive film 58 are peeled off with the oxide layer 57 on the surface of the father stamper 55 as a boundary to obtain a mother stamper 60. Patterns formed on the mother stamper 60 are reverse to patterns drawn with the EB drawing apparatus.

The mother stamper is more suitable than the father stamper when resin stampers for producing DTR media or BPMs are produced. This is because patterns formed on the DTR medium or BPM are the same as patterns drawn with the EB drawing apparatus.

A time necessary for EB drawing is generally 3 to 4 days for a 1.8 inch DTR medium and one week for a 2.5 inch DTR medium. Accordingly, it is preferable to be able to duplicate stampers from the viewpoint of mass-productivity.

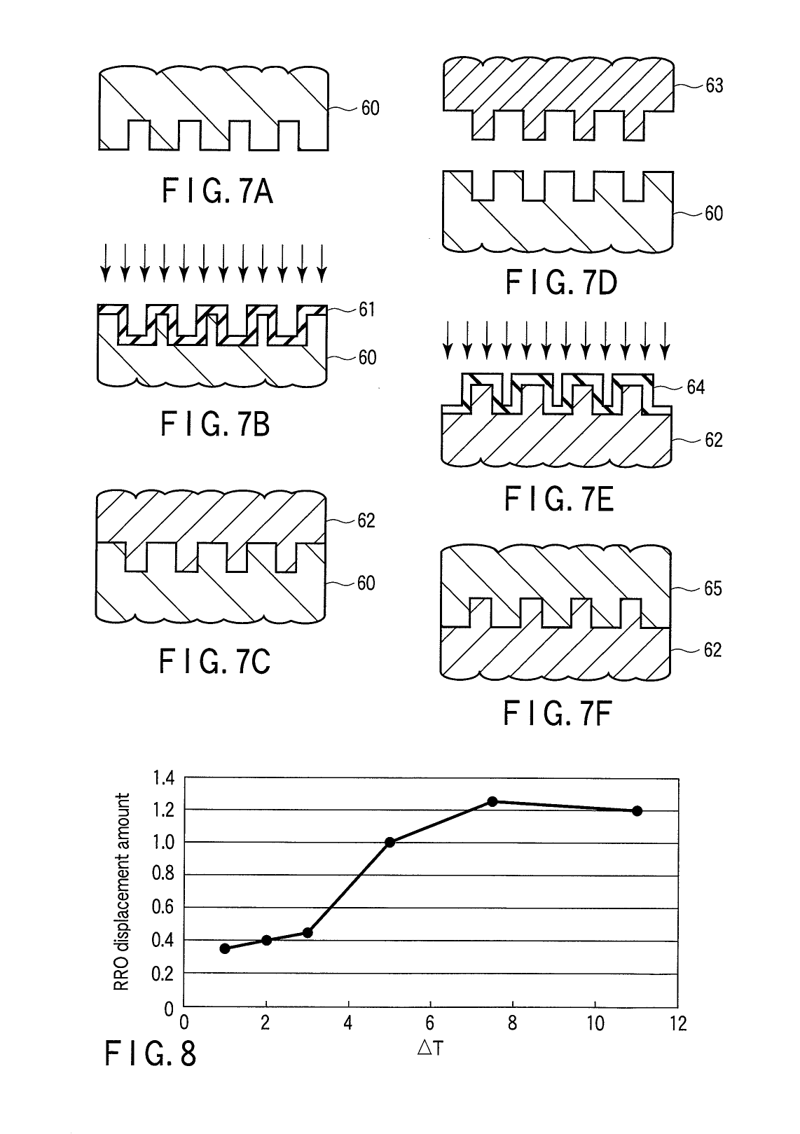

With reference to FIGS. 7A to 7F, methods of producing a son stamper and a daughter stamper, which are a duplication stamper, will be described.

As shown in FIG. 7A, a mother stamper 60 is prepared, and as shown in FIG. 7B the surface of the mother stamper 60 is oxidized by oxygen RIE to form an oxide layer 61. As shown in FIG. 7C, after a conductive film (not shown) is formed by sputtering on the surface of the oxide layer 61, an electroforming layer 62 is formed by electroforming. As shown in FIG. 7D, the electroforming layer 62 and conductive film are peeled off to form a son stamper 63. Patterns formed on the son stamper 63 are the same as those of the father stamper 55. The mother stamper 60 may be reused by surface oxidation, deposition of a conductive film, formation of an electroforming layer, and peeling off of the electroforming layer and conductive film, a son stamper 63 may be formed once more.

As shown in FIG. 7E, the surface of the son stamper 63 is oxidized by oxygen RIE to form an oxide layer 64. As shown in FIG. 7F, after a conductive film (not shown) is deposited on the surface of the oxide layer 64 by sputtering, an electroforming layer 65 is formed by electroforming. Thereafter, the electroforming layer 65 and conductive film are peeled off to prepare a daughter stamper. Patterns formed on the daughter stamper are the same as those of the mother stamper.

When the above-mentioned method is repeated, a lot of duplication stampers may be mass-produced from the father stamper.

Advantages of the invention will be described below in more detail. As described above, when a stamper is produced according to the method of the invention, the back side of the stamper is free from burrs, and an inner peripheral edge, an outer peripheral edge and a main surface of the back side lie on the same plane on the back side. Accordingly, a lifetime of the stamper is largely extended during injection molding.

The resin stamper prepared according to the method of the invention and DTR media or BPMs produced therewith are found to be smaller in RRO (repeatable run out) than ever. The RRO is also called a positional distortion in track synchronization and represents a deviation of a track from a true circle. In a stamper prepared according to a conventional method, burrs remaining on an inner periphery and an outer periphery collapse every time injection molding is repeated to result in generating distortion in the stamper itself. As a result, the RRO increases in the resin stamper and the DTR media or BPMs produced therewith.

The stamper prepared according to the method of the invention is excellent as well in safety. The inner peripheral edge and outer peripheral edge of the stamper produced according to a conventional method are formed into a form like a sharp blade. Accordingly, there is a possibility that careless handling may hurt a hand. The inner peripheral edge and outer peripheral edge of the stamper prepared according to the method of the invention are polished. Accordingly, a touch with a hand does not cause injury.

The stamper prepared according to the method of the invention may suppress warping. It is known that when a resin stamper is formed from a warped Ni stamper by injection molding and DTR media or BPMs are produced with the resin stamper, the RRO increases. Thus, it is preferable that the warping of the Ni stamper is preferably as small as possible. In the stampers prepared according to a conventional method, a radial tilt may be substantially ±0.6° in some cases. However, in the stampers prepared according to the method of the invention, the radial tilt may be suppressed to substantially ±0.2°. The phenomenon may be described as follows. In a process of polishing a back side, stress is applied on the Ni stamper to generate strain; however, the Ni stamper does not warp in this state. In a conventional method, it is considered that since punching is performed under high internal stress, the stress is alleviated at one stroke during punching, and thereby warp is generated in the Ni stamper. In the invention, it is considered that since punching is performed before the back side is polished, the stress is not alleviated and thereby the Ni stamper is inhibited from warping.

The method of the invention is also effective for inhibiting dust from adhering. A back side of a Ni stamper is mirror-polished by buffing. After the step, a cleaning step for removing slurry adhered to the back side is performed. According to a conventional method, inner and outer peripheries are punched after the mirror polishing. Therefore, grinding sludge generated during punching remains as adhered. According to the method of the invention, after the inner and outer peripheries are punched and the back side is mirror-polished, a cleaning step is performed. Thus, grinding sludge may be removed and adhering dust becomes less. Accordingly, yield improvement and cost reduction may be achieved.

Materials and individual steps used in the invention will be detailed below.

[UV Resist]

A UV resist (2P agent) is a material having UV-curability and a composition containing a monomer, an oligomer and a polymerization initiator but not a solvent.

Examples of the monomer include those shown below.
Acrylates

Bisphenol A.ethylene oxide-modified diacrylate (BPEDA)

dipentaerythritol hexa(penta)acrylate (DPEHA)

dipentaerythritol monohydroxy pentaacrylate (DPEHPA)

dipropylene glycol diacrylate (DPGDA)

ethoxylated trimethylolpropane triacrylate (ETMPTA)

glycerinpropoxy triacrylate (GPTA)

4-hydroxybutyl acrylate (HBA)

1,6-hexanediol diacrylate (HDDA)

2-hydroxyethyl acrylate (HEA)

2-hydroxypropyl acrylate (HPA)

isobornyl acrylate (IBOA)

polyethylene glycol diacrylate (PEDA)

pentaerythritol triacrylate (PETA)

tetrahydrofurfuryl acrylate (THFA)

trimethylolpropane triacrylate (TMPTA) tripropylene glycol diacrylate (TPGDA)
Methacrylates

tetraethylene glycol dimethacrylate (4EDMA)

alkyl methacrylate (AKMA)

allyl methacrylate (AMA)

1,3-butylene glycol dimethacrylate (BDMA)

n-butyl methacrylate (BMA)

benzyl methacrylate (BZMA)

cyclohexyl methacrylate (CHMA)

diethylene glycol dimethacrylate (DEGDMA)

2-ethylhexyl methacrylate (EHMA)

glycidyl methacrylate (GMA)

1,6-hexanediol dimethacrylate (HDDMA)

2-hydroxyethyl methacrylate (2-HEMA)

isobornyl methacrylate (IBMA)

lauryl methacrylate (LMA)

phenoxyethyl methacrylate (PEMA)

t-butyl methacrylate (TBMA)

tetrahydrofurfuryl methacrylate (THFMA)

trimethylolpropane trimethacrylate (TMPMA)

In particular, isobornyl acrylate (IBOA), tripropylene glycol diacrylate (TPGDA), 1,6-hexanediol diacrylate (HDDA), dipropylene glycol diacrylate (DPGDA), neopentyl glycol diacrylate (NPDA) and ethoxylated isocyanuric acid triacrylate (TITA) are preferred because these may have viscosity of 10 cP or less.

Examples of the oligomer include urethane acrylate-bases materials such as polyurethane diacrylate (PUDA) and polyurethane hexaacrylate (PUHA), and other examples include polymethyl methacrylate (PMMA), fluorinated polymethyl methacrylate (PMMA-F), polycarbonate diacrylate, and fluorinated polycarbonate methyl methacrylate (PMMA-PC-F).

Examples of the polymerization initiator include IRGACURE 184 (trade name, manufactured by Nihon Ciba-Geigy K. K.) and DAROCURE 1173 (trade name, manufactured by Nihon Ciba-Geigy K. K.).

[Removal of Residues]

Residues remaining at bottoms of recesses of the resist are removed by RIE (reactive ion etching). As a plasma source, ICP (inductively-coupled plasma) capable of forming high density plasma at low pressure is preferred. However, ECR (electron cyclotron resonance) plasma or a general parallel plate RIE apparatus may be used. Residues of the UV resist (2P agent) are removed preferably with an oxygen gas.

[Demagnetization and Etching]

When flying characteristics of a read/write head are taken in consideration, a depth of recesses is preferably set at 10 nm or less, while a thickness of a magnetic recording layer needs to be substantially 15 nm for securing signal output. In this connection, if a thickness of 10 nm in the magnetic recording layer with a thickness of 15 nm is physically removed and a remaining thickness of 5 nm is demagnetized, side erase and side read may be suppressed while securing the flying characteristics of the recording head. This makes it possible to produce DTR media and BPMs. As a method of demagnetizing the magnetic recording layer having a thickness of 5 nm, a method of exposing the magnetic recording layer to He or N₂ ions may be used. When the magnetic recording layer is exposed to He ions, while maintaining squareness of a hysteresis loop, Hc (coercivity) decreases with an exposure time to result in losing the hysteresis eventually (demagnetization). In this case, when an exposing time to a He gas is insufficient, the hysteresis excellent in the squareness (having reversal nucleation field Hn) is maintained. However, this means that a magnetic layer at the bottom of the recess has recording capacity, that is, advantages of the DTR medium or BPM are lost. On the other hand, when the magnetic recording layer is exposed to N₂ ions, the squareness of the hysteresis loop is deteriorated with the exposing time to result in losing the hysteresis eventually. In this case, while the Hn deteriorates drastically, the Hc is difficult to decrease. However, if the exposing time of N₂ gas is insufficient, a magnetic layer high in the Hc remains at the bottom of the recesses to result in losing the advantages of the DTR medium or BPM. Here, by paying attention to difference in behaviors between the demagnetization caused by He gas and the demagnetization caused by N₂ gas, a mixed gas of He+N₂ is used, and thereby, while etching the magnetic recording layer, the magnetic recording layer at the bottom of the recesses may efficiently demagnetized.

[Resist Stripping]

After the magnetic recording layer is demagnetized, the UV resist is stripped off. The UV resist is readily stripped off by treating with oxygen plasma. At this time, the etching protective layer made of carbon and remaining on the magnetic recording layer is stripped off as well.

[Protective Film Formation and After-Treatment]

Finally, a carbon protective film is formed. The carbon protective film is desirably formed by CVD from the viewpoint of improving coverage to the protrusions and recesses. However, sputtering or vacuum evaporation may be used. When the CVD method is used, a DLC film containing many sp³-bonded carbons is formed. When a thickness of the carbon protective film is less than 2 nm, the coverage deteriorates and, when the thickness of the carbon protective film exceeds 10 nm, a magnetic spacing between the head and medium becomes larger to unfavorably deteriorate SNR. A lubricant is applied to the protective film. Examples of the lubricant include perfluoropolyether, fluorinated alcohol and fluorinated carboxylic acid.

### EXAMPLES

### Example 1

According to the method shown in FIGS. 3A to 3G, a Ni stamper (father stamper) was prepared. After punching of inner and outer peripheries, slurry in which aluminum oxide particles are dispersed was used to apply buffing to mirror-polish the back side of the father stamper. When the irregularity on the back side of the resultant father stamper was measured by a stylus profilometer, it was found that inner and outer peripheral edges are free from burrs, and the inner peripheral edge, the outer peripheral edge and a main surface of the back surface lie on the same plane.

The father stamper was set to an injection molding machine and resin stampers were continuously molded under the conditions of mold clamping force of 50 t and a cycle time of 10 seconds. The surface configurations of resin stampers at 10 shots and 10,000 shots were observed with an AFM (atomic force microscope). As a result, remarkable difference was not found between the surface configurations of both resin stampers. Thus, it was found that even when the resin stampers are continuously molded, shapes of the resin stampers are not deteriorated.

### Example 2

In this Example, the surface roughness (Ra) of the back side of a Ni stamper was studied.

A Ni stamper was prepared in a manner similar to Example 1. The surface roughness (Ra) of the back side of the Ni stamper was 7 nm.

For the purpose of comparison, a Ni stamper was prepared by mechanically polishing by rotating and revolving with a polishing cloth pressed to the back side. The stamper was free from burrs on inner and outer peripheral edges of the back side but had the Ra of 30 nm or more. When the stamper was used to mold resin stampers in a manner similar to Example 1, it was found that the resin stamper is free from deterioration in shape even after 10,000 shots.

Furthermore, for the purpose of comparison, a Ni stamper whose back side is not polished was prepared and the Ni stamper was used to mold resin stampers in a manner similar to Example 1.

The RRO of the above-mentioned three types of resin stampers were evaluated with an optical disk tester (trade name: DDU-1000, manufactured by Pulstec Industrial Co., Ltd.). As a result, it was found that resin stampers injection molded from a stamper having Ra of 7 nm were smaller in the RRO than resin stampers injection molded from the non-polished Ni stamper or a stamper that has the Ra of 30 nm or more.

Furthermore, by varying conditions of buffing, Ni stampers different in the surface roughness (Ra) of the back side were prepared. Resin stampers were prepared from the Ni stampers and the RRO was evaluated in a manner similar to that described above.

Table 1 shows relationship between Ra of back sides of Ni stampers and RRO of resin stampers. From Table 1, it was found that resin stampers prepared from a Ni stamper having Ra of the back side of 7 nm or less are improved in the RRO than resin stampers prepared from a Ni stamper that is not polished. The Ra of the back side of the Ni stamper is preferably as small as possible. However, it is very difficult to make the Ra of the back side of a stamper smaller than the Ra (substantially 0.6 nm) of a substrate. Accordingly, it is said that a Ni stamper having the Ra of the back side of 0.6 to 0.7 nm may actually obtain an effect of reducing the RRO of resin stampers.

TABLE 1

| Ra on back side | RRO in resin stamper |
|---|---|
| of Ni stamper | (amount of displacement) |
| 2 nm | Small (0.5 or less) |
| 5 nm | Small (0.5 or less) |
| 7 nm | Small (0.5 or less) |
| 10 nm | Medium (less than 1.0) |
| 30 nm | Large (1.0 or more) |
| (Mechanical polishing) | |
| No polishing | Large (1.0 or more) |

### Example 3

A Ni stamper was prepared in a manner similar to Example 1. The Ra of the back side of the stamper was 7 nm. When an in-plane thickness of the stamper was measured, the maximum value was 282 μm, the minimum value was 279 μm, and difference ΔT in thickness was within 3 μm.

Furthermore, stampers to be set to a polishing machine were mirror-polished with levelness thereof varied and thereby several types of Ni stampers having the Ra of the back side of 7 nm and different in the ΔT of in-plane thickness were prepared.

Resin stampers were molded from these Ni stampers. The RRO of each of the resultant resin stampers was evaluated with an optical disk tester (trade name: DDU-1000, manufactured by Pulstec Industrial Co., Ltd.). FIG. 8 shows relationship between the difference ΔT in in-plane thicknesses of the Ni stamper and RRO displacement amount.

The RRO displacement of the resin stamper is preferably 0.5 or less. Thus, ΔT within a stamper plane is preferably 3 μm or less. The ΔT within a Ni stamper plane is preferably as small as possible. However, it is very difficult to make the ΔT smaller than 0.3 μm (substantially one thousandth of the total thickness). Accordingly, it is said that a Ni stamper having the ΔT in the range of 0.3 to 3 μm may actually achieve an effect of reducing the RRO of resin stampers.

### Example 4

A Ni stamper was prepared in a manner similar to Example 1 except that the stamper slimming shown in FIG. 3E was performed. The slimming step was applied by immersing the Ni stamper in sulfamic acid controlled to pH 2 for 30 minutes.

The stamper prepared in Example 1 had a track pitch of 75 nm, a width of protrusions of 25 nm and a width of recesses (corresponding to recording tracks) of 50 nm. The stamper prepared by slimming had a track pitch of 75 nm, a width of protrusions of 15 nm and a width of recesses of 60 nm.

### Example 5

A Ni stamper (mother stamper) was prepared according to a method shown in FIGS. 6A to 6G. Thereafter, the inner and outer peripheries were punched and the back side was mirror-polished in a manner similar to FIGS. 3F and 3G, and thereby a mother stamper was prepared. Patterns on the mother stamper had a track pitch of 75 nm and a width of recesses of 25 nm. The mother stamper was set in an injection molding machine to prepare resin stampers. As a material of the resin stamper, ZEONOR 1060R (trade name, manufactured by Zeon Corporation) was used. Thereafter, according to a method shown in FIGS. 5A to 5I, DTR media were produced. In a metal layer, Cu was used. As the UV resist (2P agent), a composition containing 85% of IBOA, 10% of PUDA and 5% of DAROCURE 1173 (trade name) was used.

The produced DTR medium had a track pitch of 75 nm, a width of recording tracks of 50 nm and a width of recesses of 25 nm. A lubricant was applied to the surface of the DTR medium. The DTR medium was installed in an HDD to evaluate characteristics thereof. As a result, positioning accuracy of the read/write head was 6 nm, and an on-track BER (bit error rate) was 10⁻⁵.

When DTR media or BPMs are produced, a Ni mother stamper or a Ni daughter stamper is preferably used. This is because the same patterns as those of the resist master plate on which patterns are drawn by EB lithography may be transferred on the media.

### Example 6

After a mother stamper was prepared according to a method described in Example 5, a son stamper was prepared according to a method shown in FIGS. 7A to 7F. Thereafter, in a manner similar to FIGS. 3F and 3G, inner and outer peripheries were processed and mirror polishing was performed on the back side and thereby a son stamper was prepared. When the irregularity of the back side of the resultant son stamper was measured with a stylus profilometer, it was found that inner and outer peripheral edges were free from burrs and the inner and outer peripheral edges and a main surface of the back side lay on the same plane.

The son stamper was set to an injection molding machine and resin stampers were continuously molded under the conditions of mold clamping force of 50 t and a cycle time of 10 seconds. Surface configurations of the resin stampers at 10 shots and 10,000 shots were observed with an AFM (atomic force microscope). As a result, remarkable difference was not found between both surface configurations. It was found that even when the son stamper is used continuously to mold resin stampers, a shape of the resin stamper does not show deterioration. Thus, it was confirmed that, also when the son stamper is used, advantages same as the case where the father stamper was used may be obtained.

### Example 7

A son stamper was prepared in a manner similar to Example 6. Subsequently, the son stamper was slimmed by immersing in sulfamic acid controlled to pH 2 for 30 minutes. Before slimming, a track pitch was 75 nm, a width of protrusions was 25 nm and a width of recesses (corresponding to recording tracks) was 50 nm. After slimming, a width of protrusions was 15 nm and a width of recesses (corresponding to recording tracks) was 60 nm.

Thereafter, as shown in FIGS. 7E and 7F, an oxide layer was formed, a conductive layer was deposited and an electroforming layer was formed, followed by peeling off the electroforming layer and conductive layer to prepare a daughter stamper. A width of recesses of the resultant daughter stamper was 15 nm.

The daughter stamper was set in an injection molding machine to prepare resin stampers. As a material of the resin stamper, ZEONOR 1060R (trade name, manufactured by Zeon Corporation) was used. Thereafter, according to the method shown in FIGS. 5A to 5I, DTR media were produced. In a metal layer, Cu was used. As the UV resist (2P agent), a composition containing 85% of IBOA, 10% of PUDA and 5% of DAROCURE 1173 (trade name) was used.

The produced DTR medium had a track pitch of 75 nm, a width of recording tracks of 60 nm and a width of recesses of 15 nm. A lubricant was applied to the surface of the DTR medium. The DTR medium was installed on an HDD to evaluate characteristics thereof. As a result, positioning accuracy of the read/write head was 6 nm, and an on-track BER (bit error rate) was 10⁻⁶.

The DTR medium produced in the Example is wider by 10 nm in the recording track width than the DTR medium produced in Example 5. Thus, the BER was improved. This effect is due to slimming.

As described above, the Ni mother stamper or Ni daughter stamper is preferably used to produce DTR media and BPMs. It is more preferred to apply stamper slimming during preparation of the son stamper from the viewpoint of mass-productivity. The stamper slimming is wet etching. Thus, unless a chemical management is applied severely, problems such as dust generation and variation of slimming rate are caused. When a father stamper is slimmed, in the case of failing in the slimming, it is necessary to restart from the EB drawing. However, the EB drawing takes such a long time as 3 days to one week and is high in risk. On the other hand, in the case of slimming the son stamper, if failed in the slimming, it is only necessary to prepare again a son stamper from a mother stamper to recover. Therefore, there is only time loss of several hours.

### Example 8

A BPM was prepared in a manner similar to Example 5 except that patterns shown in FIG. 2 were drawn by EB lithography. A bit size of the prepared BPM was 55 nm×20 nm.

In the BPM, the BER cannot be defined. Thus, an intensity of signal amplitude was evaluated. When the BPM was magnetized in one direction and installed in a drive and a read waveform was observed, the intensity of signal amplitude was 200 mV. Positioning accuracy of the read/write head was 6 nm. It was found that a BPM can be produced according to a method similar to that for a DTR medium.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A stamper comprising:
patterns corresponding either to recording tracks or to recording bits in a data region and patterns corresponding to information in a servo region in protrusions and recesses on a front side of the stamper,
wherein an inner periphery and an outer periphery are processed in such a manner that an inner peripheral edge, an outer peripheral edge and a main surface of the back side are on the same plane on a back side.

2. The stamper of claim 1, wherein roughness Ra of the back side is 7 nm or less.

3. The stamper of claim 1, wherein a deviation of thicknesses in the plane is 3 μm or less.

4. A method of producing a stamper, comprising:
applying an electron beam resist to a substrate;
drawing pattern corresponding either to recording tracks or to recording bits in a data region, and patterns corresponding to information in a servo region on the electron beam resist by electron beam lithography, followed by developing to form protrusions and recesses;
forming a conductive film on the protrusions and recesses of the electron beam resist followed by forming a Ni electroforming layer by electroforming;
peeling off the Ni electroforming layer to form a stamper;
duplicating a stamper by repeating forming and peeling-off of the Ni electroforming layer, as required; and
processing an inner periphery and an outer periphery of the stamper followed by polishing a back side of the stamper.

5. The method of claim 4, wherein the stamper is a second stamper duplicated from a first stamper, a third stamper duplicated from the second stamper, or a fourth stamper duplicated from the third stamper.

6. The method of claim 4, comprising:
peeling off the Ni electroforming layer in order to form the stamper; and
slimming the resultant stamper.
